(19) United States
(12) Patent Application Publication
(10) Pub. No.: US 2010/0156500 A1
(43) Pub. Date: Jun. 24, 2010

(54) SEMICONDUCTOR DEVICE, OUTPUT CIRCUIT AND METHOD FOR CONTROLLING INPUT/OUTPUT BUFFER CIRCUIT IN SEMICONDUCTOR DEVICE

(75) Inventors: Yasushi Matsubara, Tokyo (JP); Minari Arai, Tokyo (JP)

Correspondence Address: MORRISON & FOERSTER LLP, 1650 TYSONS BOULEVARD, SUITE 400, MCLEAN, VA, 22102, US

(73) Assignee: Elpida Memory, Inc., Tokyo (JP)

(21) Appl. No.: 12/644,956

(22) Filed: Dec. 22, 2009

(30) Foreign Application Priority Data
Dec. 24, 2008 (JP) 2008-327620

(51) Int. Cl. H03L 5/00

(52) U.S. Cl. 327/333

(57) ABSTRACT

Disclosed is a semiconductor device having an output circuit that may be used to advantage in case the semiconductor device may possibly be used under different power supply voltages. The semiconductor device includes a signal terminal having at least the function of an output terminal, a power supply terminal, and an output circuit having first and second output buffer circuits. The first and second output buffer circuits are supplied with a supply power voltage from the power supply terminal and receive an inner output signal to drive the signal terminal. The semiconductor device also includes a power supply voltage discrimination circuit that discriminates the potential level of the power supply voltage to control the operation of the output circuit based on the result of discrimination. A first output buffer circuit is activated and a second output buffer circuit is deactivated in case the power supply voltage discrimination circuit has decided that the power supply voltage is at a first potential. Both of the first and second output buffer circuits are activated in case the power supply voltage discrimination circuit has decided that the power supply voltage is at a second potential.

### FIELD OF THE INVENTION

### (Reference to Related Application)

This application is based upon and claims the benefit of the priority of Japanese patent application No. 2008-327620, filed on Dec. 24, 2008, the disclosure of which is incorporated herein in its entirety by reference thereto.

This invention relates to a semiconductor device, an output circuit and to a method for controlling an input/output buffer circuit in the semiconductor device. More particularly, this invention relates to a semiconductor device having an output circuit thought to be used at respective different power supply voltages, and to the output circuit. It also relates to a method for controlling an input/output buffer circuit in a semiconductor device thought to be used at respective different power supply voltages.

### BACKGROUND

A semiconductor device having a conventional semiconductor device including an output buffer circuit is shown in Patent Document 1. This semiconductor device includes a plurality of output buffer circuits connected in parallel one with another, The driving capability of an output driver may be varied by a user in keeping with the peripheral circuit connected to outside.

### [Patent Document 1]

JP Patent Kokai Publication No. JP-H05-55891A

### SUMMARY

The entire disclosures of above Patent Document is incorporated herein by reference thereto. The following analyses are given according to the views of the present invention.

The following analysis is made from the side of the present invention. Among up-to-date semiconductor products, there are those that are of approximately equal functions and differ only with respect to power supply voltages that are in use. In recent DRAMs, the tendency is towards using a lower power supply voltage. In these DRAMs, power supplies are conventionally developed as separate products. The reason is that, if the power supply voltages differ, it becomes necessary to perform designing with the use of the different driving capabilities of an output buffer circuit or with the use of the different input threshold levels of the input buffer circuit. It is thus necessary to develop a power supply from one power supply voltage to another, with the result that costs for development or for inventory management for mass-produced devices are increased.

In a first aspect, the present invention provides a semiconductor device comprising a signal terminal, a power supply terminal supplied with a power supply voltage, an output circuit including first and second output buffer circuits, and a power supply voltage discrimination circuit. Each of the first and second output buffer circuits is supplied with the power supply voltage from the power supply terminal. The output circuit receives inner output signals to drive the signal terminal. A power supply voltage discrimination circuit performs discrimination of a potential level of the power supply voltage to control an operation of the output circuit based on a result of the discrimination. The first output buffer circuit is activated and the second output buffer circuit is deactivated in case the power supply voltage discrimination circuit has decided that the power supply voltage is at a first potential. Both of the first and second output buffer circuits are activated in case the power supply voltage discrimination circuit has decided that the power supply voltage is at a second potential.

In a second aspect, the present invention provides a semiconductor device comprising a plurality of input/output terminals, a plurality of input terminals, a power supply terminal, a plurality of output circuits, a plurality of first input circuits, a plurality of second input circuits and a power supply discrimination circuit. The output circuits are each provided in association with the input/output terminals. Each of the output circuits includes first and second output buffer circuits that are supplied with a power supply voltage from the power supply terminal and that receive inner output signals to drive the input/output terminal associated therewith. Each of the first input circuits is associated with one of the input/output terminals and includes first and second input buffer circuits connected to the associated one of the input/output terminals. The second input circuits are each associated with one of the input terminals. Each of the second input circuits includes third and fourth input buffer circuits connected to an associated one of the input terminals. The power supply discrimination circuit discriminates the power supply voltage to control the operation of the output circuit based on the result of decision of the power supply voltage. If the power supply voltage discrimination circuit has decided that the power supply voltage is at the first potential, the first output buffers and the first and third input buffer circuits are activated, while the second output buffer circuit and the second and fourth input buffer circuits are deactivated. If the power supply voltage discrimination circuit has decided that the power supply voltage is at the second potential, the first and second output buffer circuits and the second and fourth input buffer circuits are activated and the first and third input buffer circuits are deactivated.

In a third aspect, the present invention provides an output circuit comprising first and second output buffer circuits, and a power supply voltage discrimination circuit. The first and second output buffer circuits receive inner output signals and are thereby run in operation. Output nodes of the first and second output buffer circuits are connected in common. The power supply voltage discrimination circuit discriminates a power supply voltage to control the operation of the first and second output buffer circuits based on the result of discrimination. The first output buffer circuit is activated and the second output buffer circuit is deactivated in case the power supply discrimination circuit has decided that the power supply voltage is at the first potential. Both of the first and second output buffer circuits are activated in case the power supply discrimination circuit has decided that the power supply voltage is at the second potential.

In a forth aspect, the present invention provides a semiconductor device comprising a signal terminal, a power supply terminal supplied with a power supply voltage, first and second output buffer circuits each supplied with the power supply voltage from the power supply terminal, and a power supply voltage discrimination circuit activating selected one or ones of the first and second output buffer circuits in response to a electrical potential of the power supply voltage.

The meritorious effects of the present invention are summarized as follows.

According to the present invention, such a semiconductor device whose driving capabilities for e.g. an output buffer differ with different power supply voltages used may be obtained with ease as the circuit is scarcely increased in circuit area.

The above features and advantages of the present invention will be more apparent from the following description of certain preferred exemplary embodiments taken in conjunction with the accompanying drawings.

### BRIEF DESCRIPTION OF THE DRAWINGS

FIG. 1 is a block diagram showing an output circuit and a peripheral circuit in a semiconductor device according to an Example of the present invention.

FIG. 2 is a block diagram of a first output buffer circuit according to the Example of the present invention.

FIG. 3 is a block diagram of a second output buffer circuit according to the Example of the present invention.

FIG. 4A is a circuit diagram showing a power supply discrimination circuit according to an Example 1 of the present invention.

FIG. 4B is a circuit diagram showing a power supply discrimination circuit according to an Example 2 of the present invention.

FIG. 5 is a circuit diagram of a level shift circuit according to the Example of the present invention.

FIG. 6 is a block diagram showing an output circuit and a peripheral circuit in a semiconductor device according to another Example of the present invention.

FIG. 7 is a circuit diagram showing an input buffer circuit according to the other Example of the present invention.

### PREFERRED MODES

Preferred exemplary embodiments of the present invention will now be described by referring to the drawings as necessary. It should be noted that particular drawings and reference numerals used therein, if referred to in the following description, are so referred to only by way of illustration, and are not intended to limit other possible variations of the exemplary embodiment of the present invention.

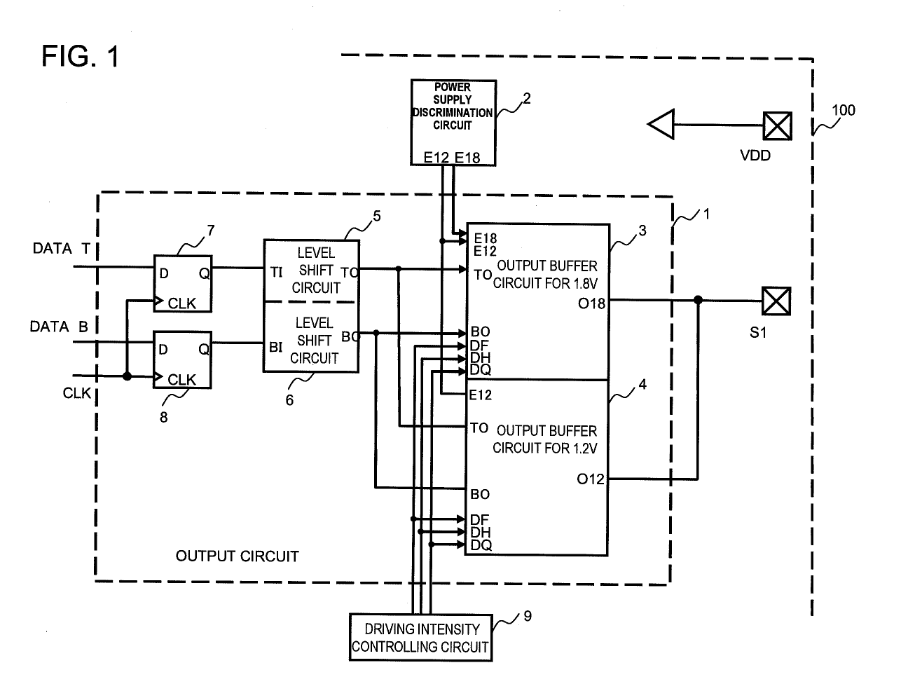

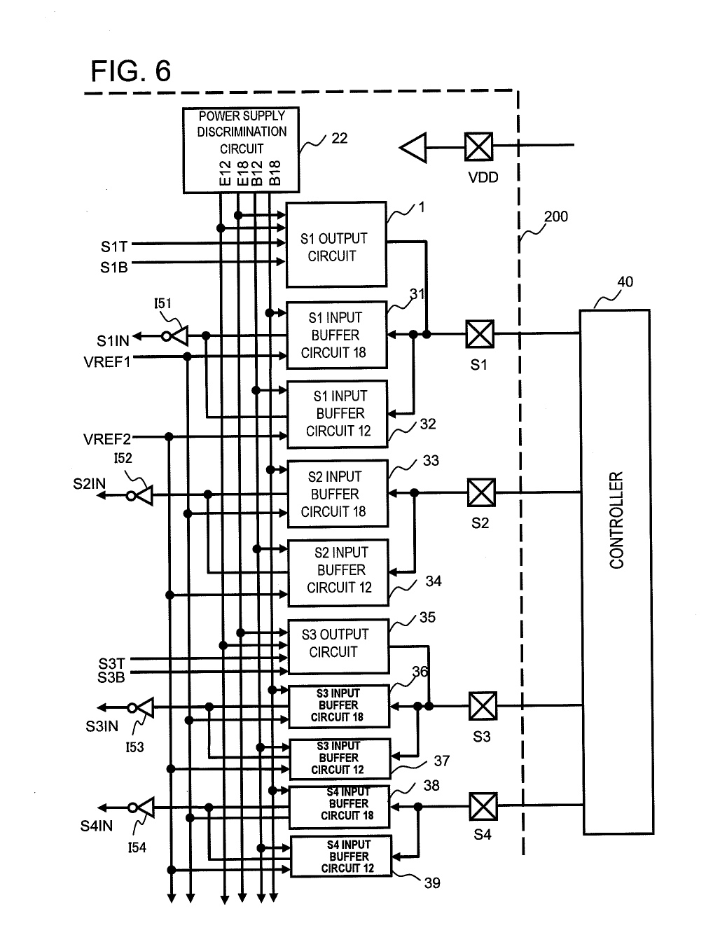

The semiconductor device according to exemplary embodiments of the present invention includes a signal terminal S1 having at least the function of an output terminal, a power supply terminal VDD, an output circuit 1, and a power supply voltage discrimination circuit (2, 22), as shown in FIGS. 1 and 6. The output circuit includes first and second output buffer circuits (3, 4) that are supplied with a supply power voltage from the power supply terminal VDD and that receive inner output signals (TI, BI) to drive the signal terminal S1. The power supply voltage discrimination circuit discriminates the potential level of the power supply voltage to control the operation of the output circuit based on the result of discrimination. The first output buffer circuit 3 is activated and the second output buffer circuit 4 is deactivated in case the power supply voltage discrimination circuit (2, 22) has decided that the power supply voltage is at a first potential (1.8V). Both of the first and second output buffer circuits (3, 4) are activated in case the power supply voltage discrimination circuit has decided that the power supply voltage is at a second potential (1.2V). Since not only the second output buffer but also the first output buffer is activated simultaneously when the power supply voltage is at the second potential, the circuit area of the output buffer circuit may be reduced in its entirety.

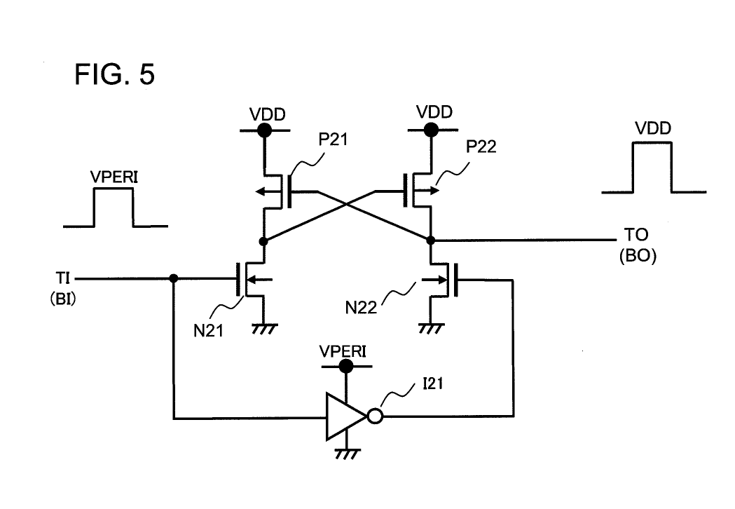

The semiconductor device of the exemplary embodiments also includes a level shift circuit (5, 6) for converting the voltage level of the inner output signals (TI, BI) into that of the power supply voltage level VDD, as shown for example in FIGS. 1 and 5. Since the power supply voltage of the internal circuit is converted by the level shift circuit into that of the power supply voltage level VDD, it is possible to make common use of the power supply voltage of the internal circuit even if different power supply voltages are supplied from outside. There is thus no necessity to change the internal circuits in keeping with the power supply voltage delivered from outside, with the exception of the input/output buffer circuits.

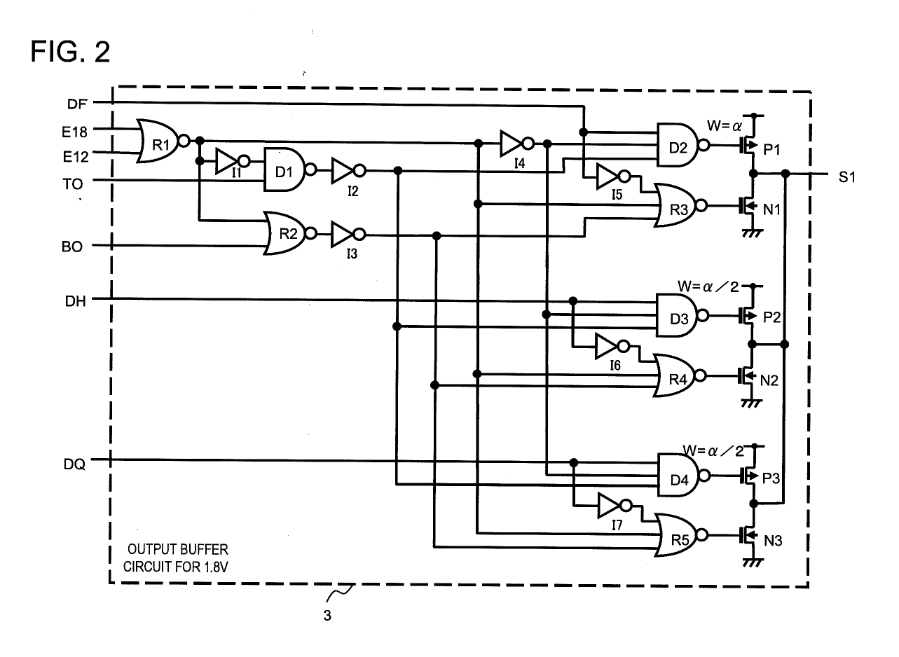

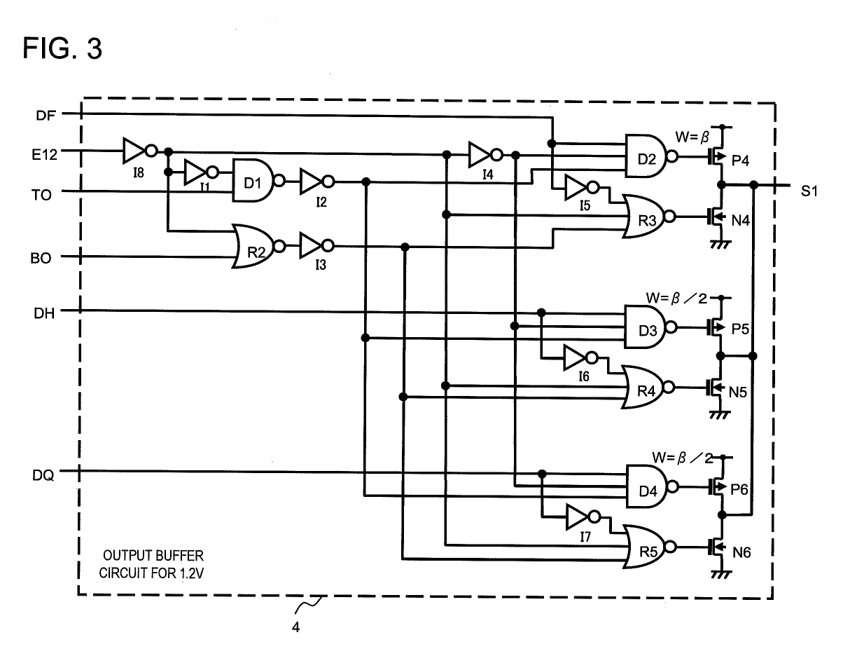

With the semiconductor device according to the exemplary embodiments, the first and second output buffer circuits each include a plurality of P-channel output buffers (P1 to P6) and a plurality of N-channel output buffers (N1 to N6), as shown in FIGS. 2 and 3. The inner output signals (TO, BO) are comprised of the first inner output signal TO that controls on/off of the P-channel output buffers (P1 to P6) and the second inner output signal BO that controls on/off of the N-channel output buffers. That is, the P-channel output buffers and the N-channel output buffers may separately be controlled to be on or off by the first and second inner output signals, respectively, so that it becomes possible to turn off both the P-channel output buffers and the N-channel output buffers to provide a high output impedance.

With the semiconductor device according to the exemplary embodiments, the number of the P-channel output buffers (P1 to P6) of the first and second output buffer circuits (3, 4) turned on simultaneously or the number of the N-channel output buffers (N1 to N6) of the first and second output buffer circuits turned on simultaneously is controlled by a set of driver intensity signal (DF, DH and DQ of FIG. 1), as shown for example in FIGS. 1 to 3. That is, the driving capability of the output buffer may be varied, as in the case of the above mentioned Patent Document 1, irrespectively of whether the power supply voltage is at the first potential or at the second potential.

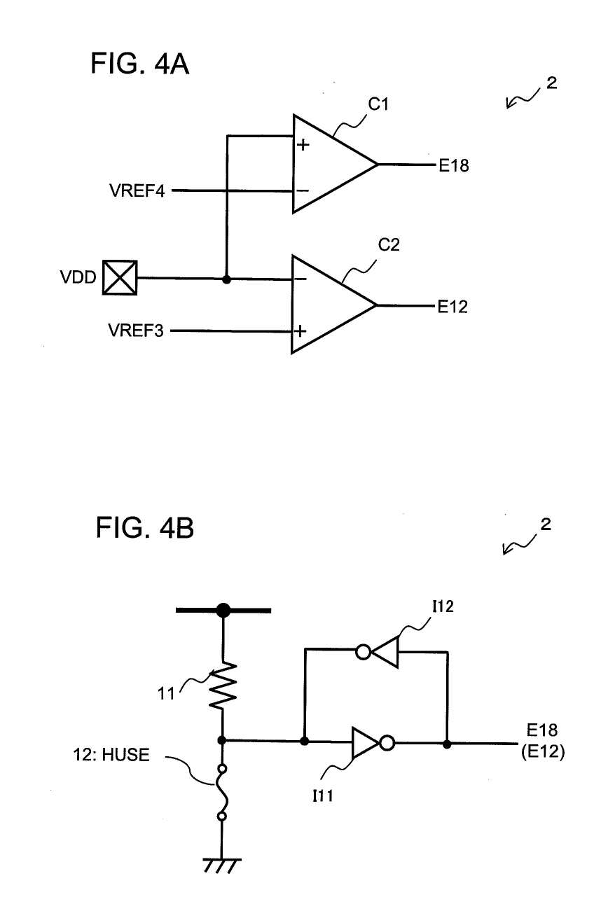

The power supply voltage discrimination circuit (2, 22) of the semiconductor device according to the exemplary embodiments includes voltage comparison circuits (C1, C2) as shown for example in FIG. 4A. The voltage comparison circuits compare the power supply voltage to the reference voltages (VREF3, VREF4) to decide the potential of the power supply voltage. With the power supply voltage discrimination circuit, having the above mentioned configuration, the power supply voltage, delivered from outside, may automatically be discriminated to change the configuration of the output buffer circuit.

The power supply voltage discrimination circuit (2, 22) of the semiconductor device according to the exemplary embodiments discriminates the power supply voltage by data stored in the non-volatile storage circuit 12, as shown for example in FIG. 4B. If data corresponding to the power supply voltage to be in use is written beforehand in the non-volatile storage circuit, such as a fuse, the power supply voltage may automatically be determined on the basis of the data stored in the non-volatile storage circuit.

With a semiconductor device according to the exemplary embodiments, the signal terminal is an input/output terminal (S1, S3), as shown in FIG. 6. The semiconductor device further includes first and second input buffer circuits (31, 32, 36, 37) connected to the input/output terminals (S1, S3), as shown for example in FIG. 6. The first input buffer circuits (31, 36) are activated and the second input buffer circuits (32, 37) are deactivated in case the power supply discrimination circuit 22 has decided that the power supply voltage is at the first potential (1.8V). The second input buffer circuits (32, 37) are activated and the first input buffer circuits (31, 36) are deactivated in case the power supply discrimination circuit 22 has decided that the power supply voltage is at the second potential (1.2V). Since the input buffer circuits are not so large in circuit area as the output buffer circuit, the input buffer circuits may alternatively be switched depending on the power supply voltage in use. By this configuration, such a semiconductor device having an input buffer circuit whose input threshold level is optimized from one power supply voltage to another may be provided in case a signal terminal is an input/output terminal.

The semiconductor device according to the exemplary embodiments further comprises input terminals (S2, S4) and third and fourth input buffer circuits (33, 34, 38, 39) connected to the input terminals (S2, S4), as shown in FIG. 6. The third input buffer circuits (33, 38) are activated and the fourth input buffer circuits (34, 39) are deactivated in case the power supply discrimination circuit 22 has decided that the power supply voltage is at the first potential (1.8V). The fourth input buffer circuits (34, 39) are activated and the third input buffer circuits (33, 38) are deactivated in case the power supply discrimination circuit has decided that the power supply voltage is at the second potential (1.2V). By this configuration, the input threshold level at the input terminal may be optimized in keeping with the power supply voltage.

The semiconductor device according to the exemplary embodiments includes a plurality of input/output terminals (S1, S3), a plurality of input terminals (S2, S4), a power supply terminal VDD, and a plurality of output circuits (1, 35), as shown for example in FIG. 6. The semiconductor device also includes a plurality of first input circuits (31, 32, 36, 37), a plurality of second input circuits (33, 34, 38, 39) and a power supply discrimination circuit (2, 22). The output circuits are each provided in association with the input/output terminals (S1, S3). Each of the output circuits includes first and second output buffer circuits (3, 4 of FIG. 1) that are supplied with a power supply voltage from the power supply terminal VDD and that receive inner output signals (S1T, S1B, S3T, S3B) to drive the input/output terminals (S1, S3) associated therewith. Each of the first input circuits is associated with one of the input/output terminals (S1, S3) and includes first and second input buffer circuits connected to the associated one of the input/output terminals (S1, S3). The second input circuits are each associated with one of the input terminals (S2, S4). Each of the second input circuits includes third and fourth input buffer circuits connected to the associated one of the input terminals (S2, S4). The power supply discrimination circuit 22 discriminates the power supply voltage to control the operation of the output circuit 1 based on the result of discrimination of the power supply voltage. If the power supply voltage discrimination circuit 22 has decided that the power supply voltage is at the first potential (1.8V), the first output buffers 3 and the first and third input buffer circuits (31, 33, 36, 38) are activated, while the second output buffer circuits 4 and the second and fourth input buffer circuits (32, 34, 37, 39) are deactivated. The first and second output buffer circuits (3, 4) and the second and fourth input buffer circuits (32, 34, 37, 39) are activated and the first and third input buffer circuits (31, 33, 36, 38) are deactivated if the power supply voltage discrimination circuit 22 has decided that the power supply voltage is at the second potential (1.2V). When the power supply voltage is at the second potential, the first output buffer circuit is activated with activation of the second output buffer circuit. Hence, an optimum driving capability may be achieved, without appreciably increasing the circuit area of the output buffer circuit, irrespectively of whether the power supply voltage is at the first potential or at the second potential. On the other hand, the input buffer circuits may alternatively be changed over depending on the power supply voltage. By this configuration, such an input buffer circuit may be obtained in which the input threshold level is optimized from one power supply voltage to another.

An output circuit according to the exemplary embodiments includes first and second output buffer circuits (3, 4) that receive inner output signals and that are thereby run in operation, and a power supply voltage discrimination circuit (2, 22), as shown in FIG. 1. Output nodes (O18, O12) of the first and second output buffer circuits are connected in common. The power supply voltage discrimination circuit discriminates a power supply voltage to control the operation of the first and second output buffer circuits based on the result of discrimination. The first output buffer circuit 3 is activated and the second output buffer circuit 4 is deactivated in case the power supply discrimination circuit (2, 22) has decided that the power supply voltage is at the first potential (1.8V). Both the first and second output buffer circuits (3, 4) are activated in case the power supply discrimination circuit has decided that the power supply voltage is at the second potential (1.2V). When the power supply voltage is at the second potential, the first output buffer circuit as well as the second output buffer circuit is activated. Hence, an optimum driving capability may be obtained, irrespectively of whether the power supply voltage is at a first potential or at a second potential, without substantially increasing the circuit area of the output buffer circuit.

The method according to the exemplary embodiments controls input/output buffer circuits (1, 31, 32, 35, 36, 37) in a semiconductor device 100 to which a plurality of different power supply voltages may possibly be supplied. The semiconductor device 100 includes first and second output buffer circuits (3, 4) and first and second input buffer circuits (31, 32, 36, 37). The first and second output buffer circuits receive common inner output signals (S1T, S1B, S3T, S3B) and are thereby run in operation. Outputs of the first and second output buffer circuits are connected to common input/output terminals (S1, S3). Input nodes of the first and second input buffer circuits (31, 32, 36, 37) are connected to the input/output terminals (S1, S3). The method comprises activating the first output buffer circuit 3 and the first input buffer circuits (31, 36) and deactivating the second output buffer circuit 4 and the second input buffer circuits (32, 37) when a first power supply voltage (1.8V) is supplied as the power supply voltage. The method also comprises activating the first and second output buffer circuits (3, 4) and the second input buffer circuits (32, 37) and deactivating the first input buffer circuits (31, 36) when a second power supply voltage (1.2V) is supplied as the power supply voltage. Thus, the first output buffer circuit is activated, as is the second output buffer circuit, when the power supply voltage is at the second potential level. Hence, an optimum driving capability may be obtained without substantially increasing the area of the output buffer circuit, irrespectively of whether the power supply voltage is at the first potential or at the second potential. In addition, since the switching between taking data from the first input buffer circuit and taking data from the second input buffer circuit is made in dependence upon the power supply voltage, the input threshold level of the input buffer circuit may be optimized from one power supply voltage to another. The present invention is now described in detail with reference to Examples.

### EXAMPLE 1

FIG. 1 is a block diagram showing an output circuit with its vicinity for a semiconductor device of Example 1 of the present invention. Thus, there are shown in FIG. 1 a power supply terminal VDD, a signal terminals S1 and an output circuit 1, along with a peripheral circuit, connected to the signal terminal S1, in a semiconductor device 100, such as a micro-computer or a memory.

The power supply terminal VDD delivers power to an output circuit 1. The voltages needed by internal circuits, other than the output circuit 1, are generated as necessary by a voltage decreasing circuit or a voltage increasing circuit, from the power supply VDD, and delivered to respective parts within the semiconductor device.

The signal terminal S1 is a signal terminal at least having the function of an output terminal. The signal terminal S1 may also be an input/output terminal, in a manner not shown in FIG. 1. In such case, an input buffer circuit, not shown, may be connected to the signal terminal S1.

Data T and B signals, generated by an internal circuit of the semiconductor device 100, are latched in data latches 7 and 8 of the output circuit 1 in synchronism with a clock signal CLK. The signal terminal S1 is driven on the basis of the so latched data signals.

The data T and B signals are complementary 1-bit signals used for controlling a P-channel output buffer and an N-channel output buffer of an output circuit, respectively. The data T signal and the data B signal are delivered to data latches 7 and 8, respectively, and thence supplied to level shift circuits 5 and 6, after having the timings adjusted as output signals. The level shift circuits 5 and 6 are used for converting the signal voltage level. That is, these level shift circuits convert the low voltage signal of the levels of a power supply VPERI of the internal circuit to the high voltage signal of the VDD level as the power supply of the output circuit. As the level shift circuit, a well-known level shift circuit, shown in FIG. 5, may be used. It should be noted that, while the power supply voltage from the power supply terminal VDD is directly supplied to most of the circuits within the output circuit 1, the power supply voltage from the power supply VPERI of the internal circuit, not shown, is also supplied to the data latches 7, 8 and to the level shift circuits 5, 6.

Output signals of the level shift circuits 5, 6 are respectively supplied to an output buffer circuit 3 for 1.8V, as a first output buffer circuit, and to an output buffer circuit 4 for 1.2V, as a second output buffer circuit. An E18 signal and an E12 signal, as control signals from a power supply discrimination circuit 2, are respectively supplied to the output buffer circuit 3 for 1.8V and to the output buffer circuit 4 for 1.2V. The power supply discrimination circuit 2 discriminates if the power supply voltage delivered from the power supply terminal VDD is 1.2V or 1.8V, and respectively outputs the signals E18 and E12 to the output buffer circuit 3 for 1.8V and to the output buffer circuit 4 for 1.2V. The signal E12 acts as enabling signal when VDD is 1.2V, while the signal E18 acts as enabling signal when VDD is 1.8V. These two enabling signals decide on the output buffer circuit, out of the output buffer circuit 3 for 1.8V and the output buffer circuit 4 for 1.2V, which is to be activated. Specifically, the output buffer circuit 3 for 1.8V is activated when one of the E18 signal and the E12 signal are HIGH in level, while being deactivated when both of the E18 signal and the E12 signal are LOW in level.

When the E12 signal is HIGH or LOW in level, the output buffer circuit 4 for 1.2V is activated or deactivated, respectively. As a consequence, the E12 signal goes HIGH in level, when VDD is 1.2V, so that both the output buffer circuit 3 for 1.8V and the output buffer circuit 4 for 1.2V are activated and are run in operation. It is thus possible to suppress the circuit area from increasing as compared to the case of simply operating only the output buffer circuit 4 for 1.2V in case the VDD is 1.2V.

A driving intensity controlling circuit 9 is a circuit that causes the driving capability of an output circuit to be changed depending on e.g. the load on the peripheral circuit. Driving intensity control signals DF, DH and DQ are coupled from the driving intensity controlling circuit 9 to each of the output buffer circuit 3 for 1.8V the output buffer circuit 4 for 1.2V. The DF signal is a full driving intensity signal, the DH signal is a half driving intensity signal and the DQ signal is a quarter driving intensity signal. It should be noted that, in case the driving intensity control signals DF, DH and DQ are all HIGH, both the output buffer circuit 3 for 1.8V and the output buffer circuit 4 for 1.2V are in full play. In case the DF signal is LOW in level and both the DH and DQ signals are HIGH in level, the output load driving capability of each of the output buffer circuit 3 for 1.8V and the output buffer circuit 4 for 1.2V is half of that of the circuits 3 and 4 when the latter are in full play. In case the DF and DH signals are LOW in level and only the DQ signal is HIGH in level, the output load driving capability of each of the output buffer circuit 3 for 1.8V and the output buffer circuit 4 for 1.2V is one quarter of that of the circuits 3 and 4 when the latter are in full play.

FIG. 2 depicts a block diagram of an output buffer circuit for 1.8V which is the first output buffer circuit in Example 1. In FIG. 2, a P-channel output buffer is comprised of a parallel connection of three P-channel transistors P1 to P3. In similar manner, an N-channel output buffer is comprised of a parallel connection of three N-channel transistors N1 to N3. As mentioned above, in case the VDD power supply is 1.8V or 1.2V, one of the E18 signal and the E12 signal goes HIGH in level, and hence the output of a NOR gate R1 goes LOW in level. This causes the output buffer circuit 3 for 1.8V to be activated and run in operation. In case the output of the NOR gate R1 is HIGH in level, none of buffer transistors is in operation.

In the following description, it is presupposed that one of the E18 signal and the E12 signal is HIGH, with the output of the NOR gate R1 being LOW. At this time, the P-channel output buffer transistor P1 is turned on when a P-channel output buffer control signal TO is HIGH and the full driver intensity signal DF is HIGH. The N-channel output buffer transistor N1 is turned on when an N-channel output buffer control signal BO is LOW and the full driver intensity signal DF is HIGH. The logic states of the remaining output buffer transistors P2, N2, P3 and N3 are set so that the respective output buffer transistors will be turned on or off depending on the combination of the logic levels of the P-channel output buffer control signal TO and the N-channel output buffer control signal BO and the driver intensity control signals DH and DQ.

The transistor sizes of the P-channel output buffer transistor P1, N-channel output buffer transistor N1, the remaining P-channel output buffer transistors P2, P3 and the remaining N-channel output buffer transistors N2, N3 are set so that the driving capabilities of the transistors P1 and N1 will be twice those of the transistors P2, P3 and twice those of the transistors N2, N3. Specifically, the P-channel output buffer transistor P1 and the N-channel output buffer transistor N1 are of a gate width W equal to α, whereas the P-channel output buffer transistors P2, P3 and the N-channel output buffer transistors N2, N3 are each of a gate width E equal to α/2. Thus, out of the parallel connected P-channel output buffer transistors and the parallel connected N-channel transistors, those transistors which are turned on simultaneously may be controlled by the intensity control signals DF, DH and DQ to set the driving capabilities of the output buffer transistors to ½ or ¼ with ease.

FIG. 3 depicts a block diagram showing a second output buffer circuit for 1.2V of Example 1. Specifically, the second output buffer circuit 4 is an output buffer circuit for 1.2V. The output buffer circuit 4 for 1.2V of FIG. 3 is substantially the same as the output buffer circuit 3 for 1.8V of FIG. 2, however, an inverter 18 is used in FIG. 3 in place of the NOR gate R1 used in FIG. 2 to receive the signals E12 and E18. With the output buffer circuit 3 for 1.8V, shown in FIG. 2, the NOR gate R1 is set to LOW to activate the output buffer circuit when one of the E18 signal and the E12 signal is HIGH in level. With the output buffer circuit 4 for 1.2V, shown in FIG. 3, the output of the inverter 18 is set to LOW to activate the output buffer circuit only when the E12 signal 12 is HIGH, without dependency upon the signal level of the E18 signal. In addition, since the output buffer transistors (P4 to P6 and N4 to N6) in FIG. 3 are each of a gate width different from the output buffer circuit for 1.8V, reference marks different from those used in FIG. 2 are used to depict the output buffer transistors. The sizes of the output buffer transistors will be explained later on. In other respects, the configuration as well as the operation of FIG. 3 is the same as those of FIG. 2, and hence is not explained in detail.

An example configuration of the power supply discrimination circuit 2 of FIG. 1 will now be described. FIG. 4A shows a first example configuration. With the present first example configuration, the potential at a power supply terminal VDD is compared to reference voltages VREF4, VREF3, generated within the interior of a semiconductor device, by voltage comparator circuits C1, C2, respectively. Based on the result of comparison, a signal E12 that goes HIGH for the power supply voltage VDD of 1.2V and another signal E18 that goes HIGH for the power supply voltage VDD of 1.8V are generated. For example, if VREF3 and VREF4 are set to 1.3V and 1.7V, in FIG. 4A, respectively, the signals E12 and E18 become HIGH and LOW, respectively, for the potential of VDD of the power supply terminal such that VDD<1.3V. If VDD>1.7V, the signals E12 and E18 become LOW and HIGH, respectively. If it is necessary to provide a lower limit voltage for the E12 signal being HIGH and an upper limit voltage for the E18 signal being HIGH, such limit voltages may be detected by a comparator circuit newly added for detecting the lower limit voltage for the E12 signal being HIGH and another comparator circuit newly added for detecting the upper limit voltage for the E18 signal being HIGH.

FIG. 4B shows a second example configuration of the power supply discrimination circuit 2. The present second example configuration is applied to such a case where whether the semiconductor device is to be used with the power supply of 1.2V or with the power supply of 1.8V is determined from the outset. With the example configuration of FIG. 4B, whether the semiconductor device is used with the power supply of 1.2V or with the power supply of 1.8V is written in a fuse 12 beforehand. Whether the fuse has been broken or not is to correspond to whether the semiconductor device is to be used with the power supply of 1.2V or with the power supply of 1.8V. The power supply voltage is divided by a resistor 11 and the fuse 12, which is broken or not, and the so divided voltage is decided by inverters 111, 112 to provide an E18 signal or an E12 signal. The fuse 12 may be broken once for all and, if broken once, may not be restored to its original state. Hence, the present second example configuration is valid in case it is irrevocably decided beforehand whether the semiconductor device of interest is to be used with the power supply of 1.2V or with the power supply of 1.8V. In FIG. 4B, the power supply voltage is written with the use of the fuse 12 as a non-volatile memory. However, the power supply voltage may also be written in, for example, a flash memory other than the fuse. In this case, later re-writing is also possible. A bonding option may also be used, that is, the logic state of a bonded terminal may be used for deciding on the particular power supply voltage. In the second example configuration, as mentioned above, the power supply voltage to be in use is decided at the outset, and the so written data of the non-volatile memory is read out later to decide on the power supply voltage.

In the above mentioned first and second example configurations of the power supply discrimination circuit, the power supply voltage delivered from outside to the power supply terminal VDD may be discerned without providing a new external terminal. The power supply voltage delivered from outside may possibly be set by such external terminal. This is however not desirable with a device, such as DRAM, regulated by reference prescriptions, because there lacks the provision of such new external terminals in the prescriptions. With the power supply voltage discrimination circuit according to the above mentioned first or second example configurations, the power supply voltage may be discerned without alteration of the prescriptions for the devices.

FIG. 5 depicts circuit diagrams of the level shift circuits 5 and 6. The configuration of the level shift circuit is routine and hence is not described in detail. Briefly, the level shift circuit converts the voltage level of a signal TI or BI of the power supply VPERI system of the internal circuit into a signal TO or BO of the power supply VDD system. With the use of the level shift circuit, the signal of the VPERI system may be converted to a signal of the voltage level of the VDD system which is higher than that of the signal of the VPERI system.

The way of deciding the transistor size of the output buffer transistors in FIGS. 2 and 3 is now described. The gate width/length of a transistor is decided by designing in association with the output terminal and the load which lies beyond (CR). It is supposed for simplicity that the drain-to-source voltage Vds of a transistor ranges between 1.8V and 1.2V. The ratio between the size α of the output buffer circuit for 1.8V and that β of the output buffer circuit for 1.2V is determined from the following equation (1):

1.8/1.2=(α+β)/α (1)

For example, if α=300 [μm], β=150 [μm]. That is, if the power supply voltage VDD is 1.2V, not only the transistor of the output buffer circuit for 1.2V but the transistor of the output buffer circuit for 1.8V is activated simultaneously. Hence, the transistor size of the output buffer circuit for 1.2V may be reduced.

It is supposed that, with the power supply voltage VDD=1.2V, the transistor of the output buffer circuit for 1.8V is not activated simultaneously and only the transistor of the output buffer circuit for 1.2V is activated. It is then necessary that the transistor size of the second output buffer circuit for 1.2V is equal to 450 [μm] which is (α+β). That is, by simultaneously activating the output buffer circuit for 1.8V and the second output buffer circuit for 1.2V, in accordance with the present Example, it is possible to reduce the transistor size of the output buffer circuit for 1.2V by a factor of 3.

On a side downstream of the level shift circuits 5, 6, signals of voltage amplitudes differing in dependence upon the power supply voltage of VDD are applied to the respective transistors. As a first case, it is supposed that VDD=1.8V is supplied. In this case, the power supply voltage of 1.8V is applied to the gate of each transistor of the output buffer circuit 3 for 1.8V and to the gate of each transistor of the output buffer circuit 4 for 1.2V. It is thus desirable that each transistor of the output buffer circuit for 1.2V is constructed as a high voltage withstand transistor with a gate withstand voltage of not less than 1.8V. To prevent the sorts of the transistors from increasing wastefully, it is desirable to use the transistor of the same withstand voltage for the transistor of the output buffer circuit 3 for 1.8V and for the transistor of the second output buffer circuit 4 for 1.2V.

As a second case, it is supposed that VDD=1.2V is supplied. In order for both of the output circuits to be in operation, the transistors (NMOS transistors) of the output buffer circuit 3 for 1.8V need to be run in operation with the gate voltage of 1.2V. That is, the threshold value voltage of each NMOS transistor of the output buffer circuit 3 for 1.8V needs to be not higher than 1.2V.

The above mentioned Example 1 is directed to a system that uses two power supplies. The present invention may also be directed to a system that uses three or more power supplies. If the present invention is applied to such system, employing three or more power supplies, the withstand voltage of each transistor may be made to match to the highest power supply. On the other hand, the threshold voltage of each transistor, in particular an NMOS transistor, may be made to match to the lowest power supply.

### EXAMPLE 2

FIG. 6 depicts a block diagram showing a portion of an interface of a semiconductor device 200 to a controller 40 of Example 2. The semiconductor device 200 may be of any suitable device type. For example, the semiconductor device 200 may be a DRAM, in which case the controller may be a CPU or a memory controller. In FIG. 6, those parts which are the same as those shown in FIG. 1 are depicted by the same reference numerals. The semiconductor device 200 includes a power supply terminal VDD, input/output terminals S1, S3 and input terminals S2, S4. The power supply terminal VDD is the same as the power supply terminal VDD of Example 1, and the supply power is afforded from the controller 40. The input/output terminals S1, S3 and the input terminals S2, S4 are connected to the controller 40 via external conductors, not shown. Although a sole power supply terminal is provided in FIG. 6, a plurality of power supply terminals may be provided depending on the particular application of the power supply. Within the inside of the semiconductor device 200, the power supply needed for the operation of the internal circuit is generated by a voltage raising circuit and by a voltage lowering circuit based on the power delivered from the power supply terminal VDD.

To the input/output terminal S1, there are connected, in addition to the output circuit 1 of Example 1, an S1 input buffer circuit 18, as a 1.8V system input circuit, and an S1 input buffer circuit 12, as a 1.2V system input circuit. The terminal S1 thus has, in addition to the function of an output terminal of Example 1, the function as an input terminal that takes a signal, output from the controller 40, into the inside of the semiconductor device 200. The input circuit separately has an input circuit for the 1.8V system and another input circuit for the 1.2V system, so that the input threshold levels for the case of inputting the 1.8 V system signal and for the case of inputting the 1.2 V system signal may be set independently. As voltages that become the reference of the input threshold levels, a reference voltage signal VREF1 is input to the input circuit of the 1.8V system, and another reference voltage signal VREF2 is input to the input circuit of the 1.2V system. An S1 output circuit 1 is the same in circuit configuration to the circuit 1 of Example 1 and hence the description thereof is dispensed with.

An S3 output circuit 35, connected to the input/output terminal S3, an S3 input buffer circuit 18, as an input circuit for the 1.8V system, and an S3 input buffer circuit 12, as an input circuit for the 1.2V system, are the same in circuit configuration to the output circuits and the input buffer circuits connected to the input/output terminal S1.

To the input terminal S2 or to the input terminal S4, no output circuit is connected, but an input circuit for the 1.8V system and an input circuit for the 1.2V system are connected. The functions of the input terminals S2, S4 correspond to the functions of the input/output terminals S1, S3 less the functions as the output terminals. That is, the input terminals S2, S4 possess the functions only of taking signals output from the controller 40 into the inside of the semiconductor device 200.

The power from the power supply VDD is directly supplied to the output circuits 1, 35, however, the power from an internal power supply VPERI is supplied to the input buffer circuits (31 to 34 and 36 to 39), in a manner not shown in FIG. 6.

The semiconductor device 200 includes a power supply voltage discrimination circuit 22 that controls the respective output circuits, input buffer circuits of the 1.8V system and input buffer circuits of the 1.2V system. In contradistinction from the power supply discrimination circuit 2 that outputs only the E18 signal and the E12 signal of Example 1, the power supply voltage discrimination circuit 22 outputs a B18 signal and a B12 signal, in addition to the E18 signal and the E12 signal. The B18 signal controls the input buffer circuits (31, 33, 36, 38) of the 1.8V system, and affords a constant current bias voltage to the associated input buffer circuits when the power supply voltage is 1.8V. The B18 signal becomes OV when the power supply voltage is different from 1.8V. In similar manner, the B12 signal controls the input buffer circuits (32, 34, 37, 39) of the 1.2V system, and affords a constant current bias voltage to the input buffer circuits when the power supply voltage is 1.2V. The B12 signal becomes OV when the power supply voltage is different from 1.2V. It should be noted that the signals B18 and B12 may readily be generated by a well-known constant current source circuit and a current mirror circuit, based on the E18 and E12 signals, respectively. Hence, detailed description of the internal circuit is dispensed with.

When the power supply voltage is 1.8V, the input buffer circuits 31, 33, 36 and 38 of the 1.8V system and the output buffer circuits for 1.8V of the output circuits 1, 35 are activated by the E18, E12, B18 and B12 signals output from the power supply discrimination circuit 22. On the other hand, the input buffer circuits 32, 34, 37 and 39 of the 1.2V system and the output buffer circuits for 1.2V of the output circuits 1, 35 are deactivated. Also, when the power supply voltage is 1.2V, the input buffer circuits 32, 34, 37 and 39 of the 1.2V system, the output buffer circuits for 1.2V and the output buffer circuits for 1.8V and for 1.2V of the output circuits 1, 35 are activated, while the input buffer circuits 31, 33, 36 and 38 of the 1.8V system are deactivated.

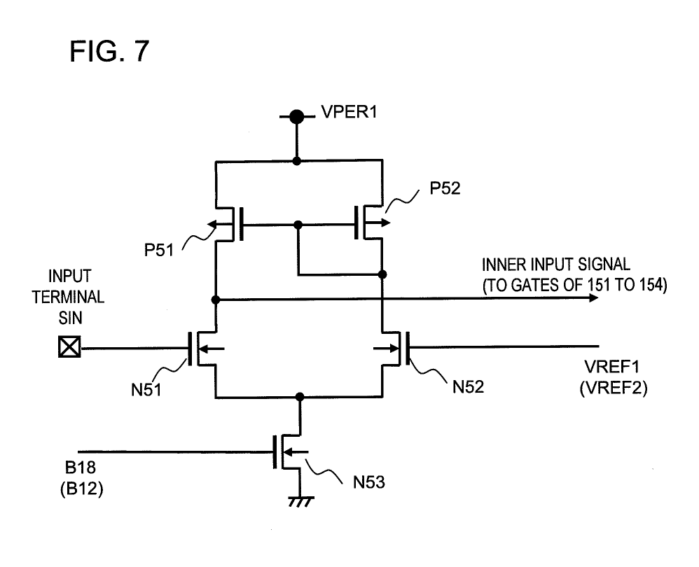

FIG. 7 depicts a circuit diagram showing input buffer circuits 31 to 34 and 36 to 39. The input buffer circuits of the 1.2V system and the 1.8V system may be implemented by the configuration of FIG. 7. In this figure, each input buffer circuit may be constructed and designed as a voltage comparator circuit that compares the voltage input from an input terminal SIN (any of S1 to S4 of FIG. 6) to the reference voltage VREF1 or VREF2. The result of comparison is delivered to the inside of the semiconductor device 200 as inner input signals (SlIN to S41N). The power supply for the input buffer circuit is delivered from the inner power supply VPERI, as previously mentioned. The input threshold voltage of the input buffer circuit is set to one-half the voltage of the power supply terminal VDD. The voltage of 0.9V is delivered as the reference voltage VREF1 to the input buffer circuits of the 1.8V system, while the voltage of 0.6V is delivered as the reference voltage VREF2 to the input buffer circuits of the 1.2V system. These reference voltages are one-half the corresponding VDD voltages. An N-channel transistor N53 operates as a constant current source transistor and, when a constant current bias voltage is applied from the B18 or B12 signal to the gate of the transistor, the current may flow through a differential pair composed of N-channel transistors N51, N52 to activate the entire input buffer circuit. On the other hand, if the B18 or B12 signal is zero, the N-channel transistor N53 inhibits the current from flowing through the differential pair to deactivate the entire input buffer circuit.

The drains of the P-channel transistor P51 and the N-channel transistor N51 are connected together and output as an inner input signal. Referring to FIG. 6, the inner input signals output from the input buffer circuits of the 1.2V system and the inner input signals output from the input buffer circuits of the 1.8V system are connected in a wired-OR fashion and connected to the gates of inverter circuits 151 to 154. By the B18 signal and the B12 signal, one of the pair inner input signals outputs an inverted signal of the input terminal, with the other inner input signal representing high impedance.

By using, as an input buffer circuit, a voltage comparator circuit with a different reference voltage in dependence upon the voltage delivered from the power supply terminal VDD, it is possible to implement an input buffer circuit having an optimum input level with respect to plural sorts of power supply voltages.

The above Examples are directed to a case where power supply voltage terminals are used with two sorts of power supply voltages of 1.8V and 1.2V. However, the number of the power supplies or the values of the power supply voltages are naturally not limited to those of the Examples, such that three or more power supplies may also be used.

Other preferable modes of the present invention are summarized in the following.

### (Additional Mode 1)

A method for controlling an input/output buffer circuit in a semiconductor device to which a plurality of different power supply voltages may possibly be supplied;

said semiconductor device including:

first and second output buffer circuits that receive a common inner output signal and that are thereby run in operation; said first and second output buffer circuits having output nodes connected to a common input/output terminal; and

first and second input buffer circuits having input nodes connected to said input/output terminal;

said method comprising:

activating said first output buffer circuit and said first input buffer circuit and deactivating said second output buffer circuit and said second input buffer circuit when a first power supply voltage is supplied as said power supply voltage; and

activating said first and second output buffer circuits and said second input buffer circuit and deactivating said first input buffer circuit when a second power supply voltage is supplied as said power supply voltage.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A semiconductor device comprising:
a signal terminal;
a power supply terminal supplied with a power supply voltage;
an output circuit including first and second output buffer circuits each supplied with the power supply voltage from the power supply terminal, and receiving inner output signals to drive said signal terminal; and
a power supply voltage discrimination circuit that performs discrimination of a potential level of the power supply voltage to control an operation of said output circuit based on a result of the discrimination; wherein
said first output buffer circuit is activated and said second output buffer circuit is deactivated in case said power supply voltage discrimination circuit has decided that said power supply voltage is at a first potential; both of said first and second output buffer circuits being activated in case said power supply voltage discrimination circuit has decided that said power supply voltage is at a second potential.

2. The semiconductor device according to claim 1 wherein said output circuit further comprises a level shift circuit that converts a voltage level of said inner output signal to a voltage level of said power supply voltage.

3. The semiconductor device according to claim 1, wherein
said first and second output buffer circuits each includes a plurality of P-channel output buffers and a plurality of N-channel output buffers;
said inner output signal includes a first inner output signal that controls on/off of said P-channel output buffers and a second inner output signal that controls on/off of said N-channel output buffers.

4. The semiconductor device according to claim 3, wherein
a number of said P-channel output buffers of said first and second output buffer circuits turned on simultaneously and a number of said N-channel output buffers of said first and second output buffer circuits turned on simultaneously are controlled by a driver intensity signal.

5. The semiconductor device according to claim 1, wherein
said power supply discrimination circuit includes a voltage comparator circuit that compares said power supply voltage to a reference voltage to discriminate the potential of said power supply voltage.

6. The semiconductor device according to claim 1, wherein
said power supply discrimination circuit discriminates said power supply voltage by data stored beforehand in a non-volatile storage circuit.

7. The semiconductor device according to claim 1, wherein
said signal terminal is an input/output terminal;
said semiconductor device further comprising:
first and second input buffer circuits connected to said input/output terminal;
said first input buffer circuit being activated and said second input buffer circuit being deactivated in case said power supply discrimination circuit has decided that said power supply voltage is at said first potential;
said second input buffer circuit being activated and said first input buffer circuit being deactivated in case said power supply discrimination circuit has decided that said power supply voltage is at said second potential.

8. The semiconductor device according to claim 1, further comprising:
an input terminal; and
third and fourth input buffer circuits connected to said input terminal;
said third input buffer circuit being activated and said fourth input buffer circuit being deactivated in case said power supply discrimination circuit has decided that said power supply voltage is at said first potential;
said fourth input buffer circuit being activated and said third input buffer circuit being deactivated in case said power supply discrimination circuit has decided that said power supply voltage is at said second potential.

9. A semiconductor device comprising:
a plurality of input/output terminals;
a plurality of input terminals;
a power supply terminal;
a plurality of output circuits each provided in association with said input/output terminals; each of said output circuits including first and second output buffer circuits that are supplied with a power supply voltage from said power supply terminal and that receive inner output signals to drive the input/output terminal associated therewith;
a plurality of first input circuits each associated with one of said input/output terminals; each of said first input circuits including first and second input buffer circuits connected to the associated one of said input/output terminals;
a plurality of second input circuits each associated with one of said input terminals; each of said second input circuits including third and fourth input buffer circuits connected to the associated one of said input terminals; and
a power supply discrimination circuit that discriminates said power supply voltage to control the operation of said output circuit based on the result of discrimination of said power supply voltage; wherein
if said power supply voltage discrimination circuit has decided that said power supply voltage is at a first potential, said first output buffers and said first and third input buffer circuits are activated, while said second output buffer circuit and said second and fourth input buffer circuits are deactivated;
said first and second output buffer circuits and said second and fourth input buffer circuits being activated and said first and third input buffer circuits being deactivated if said power supply voltage discrimination circuit has decided that said power supply voltage is at a second potential.

10. An output circuit comprising:
first and second output buffer circuits that receive inner output signals and that are thereby run in operation; said first and second output buffer circuits having output nodes connected in common; and
a power supply voltage discrimination circuit that discriminates a power supply voltage to control the operation of said first and second output buffer circuits based on the result of discrimination; wherein
said first output buffer circuit is activated and said second output buffer circuit is deactivated in case said power supply discrimination circuit has decided that said power supply voltage is at a first potential;
said first and second output buffer circuits both being activated in case said power supply discrimination circuit has decided that said power supply voltage is at a second potential.

11. The output circuit according to claim 10 further comprising:
a level shift circuit that converts the voltage level of said inner output signal to a voltage level of said power supply voltage.

12. The output circuit according to claim 10, wherein
said first and second output buffer circuits each include a plurality of P-channel output buffers and a plurality of N-channel output buffers;
said inner output signal being a first inner output signal that on/off controls the P-channel output buffers of said first and second output circuits and a second inner output signal that on/off controls the N-channel output buffers of said first and second output buffer circuits.

13. The output circuit according to claim 12, wherein
the number of the P-channel output buffers of said first and second output circuits, turned on simultaneously, or the number of the N-channel output buffers of said first and second output circuits, turned on simultaneously, is controlled by a driver intensity signal.

14. The output circuit according to claim 10 wherein
said power supply discrimination circuit includes a voltage comparison circuit that compares the power supply voltage to a reference voltage to discriminate the potential of the power supply voltage.

15. The output circuit according to claim 10 wherein
said power supply discrimination circuit discriminates the power supply voltage based on data stored in a non-volatile storage circuit beforehand.

16. A semiconductor device comprising:
a signal terminal;
a power supply terminal supplied with a power supply voltage;
first and second output buffer circuits each supplied with the power supply voltage from the power supply terminal; and
a power supply voltage discrimination circuit activating selected one or ones of the first and second output buffer circuits in response to a electrical potential of the power supply voltage.

17. The semiconductor device according to claim 16, wherein the power supply voltage discrimination circuit is supplied with a reference voltage, activates both of the first and second output buffer circuits when the power supply voltage is smaller than the reference voltage, and activates only selected one of the first and second output buffer circuits when the power supply voltage is larger than the reference voltage.
